(19) United States
(12) Patent Application Publication
(10) Pub. No.: US 2023/0274963 A1
(43) Pub. Date: Aug. 31, 2023

(54) SEMICONDUCTOR MANUFACTURING DEVICE, WAFER CONVEYANCE SYSTEM, WAFER CONVEYANCE METHOD, AND NON-TRANSITORY COMPUTER READABLE MEDIUM FOR WAFER CONVEYANCE SYTEM

(71) Applicant: KIOXIA CORPORATION, Tokyo (JP)

(72) Inventor: Teppei KITA, Kuwana Mie (JP)

(73) Assignee: KIOXIA CORPORATION, Tokyo (JP)

(21) Appl. No.: 17/895,425

(22) Filed: Aug. 25, 2022

(30) Foreign Application Priority Data
Feb. 25, 2022 (JP) 2022-028095

(51) Int. Cl. H01L 21/677; H01L 21/67

(52) U.S. Cl. CPC H01L 21/67742; H01L 21/67766; H01L 21/67276

(57) ABSTRACT

A semiconductor manufacturing device includes a first conveyance unit; a processing unit in contact with the first conveyance unit; a conveyance module provided in the first conveyance unit and including an arm driving unit and an arm supporting unit; and a conveyance arm including a first conveyance module and a second conveyance module that can be driven independently. The first conveyance module and the second conveyance module can be physically combined with and/or separated from each other.

### CROSS-REFERENCE TO RELATED APPLICATION(S)

This application is based upon and claims the benefit of priority from Japanese Patent Application No. 2022-028095, filed Feb. 25, 2022, the entire contents of which are incorporated herein by reference.

### FIELD

Embodiments described herein relate generally to a semiconductor manufacturing device, a wafer conveyance system, a wafer conveyance method, and a non-transitory computer readable medium for a wafer conveyance system.

### BACKGROUND

Generally, a conveyance system including robots placed in a locally cleaned treatment room. A conveyance process can continue even for a failed robot. In case of a failure, a non-failed robot continues the conveyance process while performing the conveyance process of the failed robot, and thus it is likely that an operating efficiency of an entire conveyance system is reduced.

### DESCRIPTION OF THE DRAWINGS

FIG. 1 is a schematic diagram illustrating an overall configuration of a wafer conveyance system according to a first embodiment.

FIG. 2 is a schematic diagram illustrating a configuration of a semiconductor manufacturing device.

FIG. 3A is a schematic diagram illustrating a configuration of a conveyance arm.

FIG. 3B is a schematic diagram illustrating configurations of first to fourth conveyance modules.

FIG. 4 is a flowchart illustrating an example of a flow of operations of a wafer conveyance method when a failure occurs.

FIG. 5A is a plan view illustrating the semiconductor manufacturing device in a normal operation mode.

FIG. 5B is a plan view illustrating the semiconductor manufacturing device when a conveyance error occurs.

FIG. 5C is a plan view illustrating the semiconductor manufacturing device after the conveyance error occurs.

FIG. 5D is a side view illustrating the semiconductor manufacturing device after the conveyance error occurs.

FIG. 5E is a plan view illustrating the semiconductor manufacturing device when a first conveyance module and a second conveyance module are separated from each other.

FIG. 5F is a plan view illustrating the semiconductor manufacturing device when the first conveyance module is retracted.

FIG. 5G is a plan view illustrating the semiconductor manufacturing device when a process is resumed.

FIG. 5H is a plan view illustrating the semiconductor manufacturing device when the first conveyance module in which a conveyance error is cleared and second to fourth conveyance modules are combined.

### DETAILED DESCRIPTION

Embodiments provide a semiconductor manufacturing device, a wafer conveyance system, a wafer conveyance method, and a non-transitory computer readable medium for a wafer conveyance system.

In general, according to one embodiment, a semiconductor manufacturing device includes a first conveyance unit; a processing unit in contact with the first conveyance unit; a conveyance module provided in the first conveyance unit and including an arm driving unit and an arm supporting unit; and a conveyance arm including a first conveyance module and a second conveyance module that can be driven independently. The first conveyance module and the second conveyance module can be physically combined with and/or separated from each other.

In addition, embodiments described below exemplify devices and methods for embodying the technical idea, and do not specify a material, a shape, a structure, an arrangement, and the like of each component. This embodiment may be modified in various ways within the scope of the claims.

### First Embodiment

### Configuration of Wafer Conveyance System

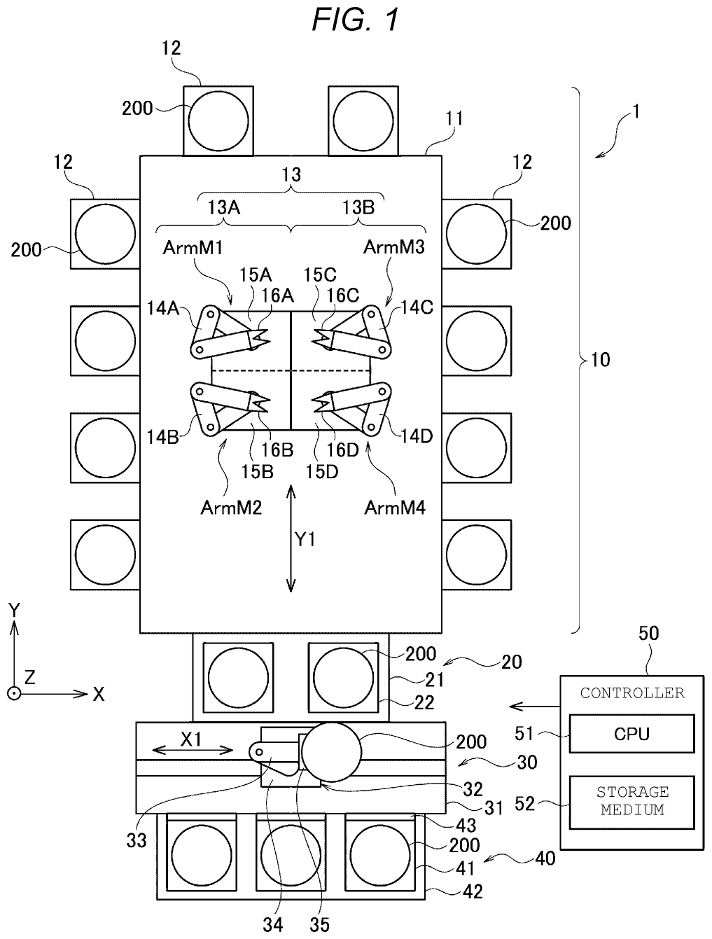

A wafer conveyance system 1 according to a first embodiment is described. FIG. 1 is a schematic diagram illustrating an overall configuration of the wafer conveyance system 1 according to the first embodiment. In the following description, an XYZ coordinate system, which is an example of an orthogonal coordinate system, is used. That is, a direction along a short side of a first conveyance unit 11 that configures the wafer conveyance system 1 is defined as an X axis, and a direction along a long side of the first conveyance unit 11 is defined as a Y axis. In addition, a direction orthogonal to an XY plane is defined as a Z axis. The related orthogonal coordinate system may also be illustrated in other drawings used in the following description.

As illustrated in FIG. 1, the wafer conveyance system 1 includes a semiconductor manufacturing device 10, a delivery unit 20, a second conveyance unit 30, an integration unit 40, and a controller 50.

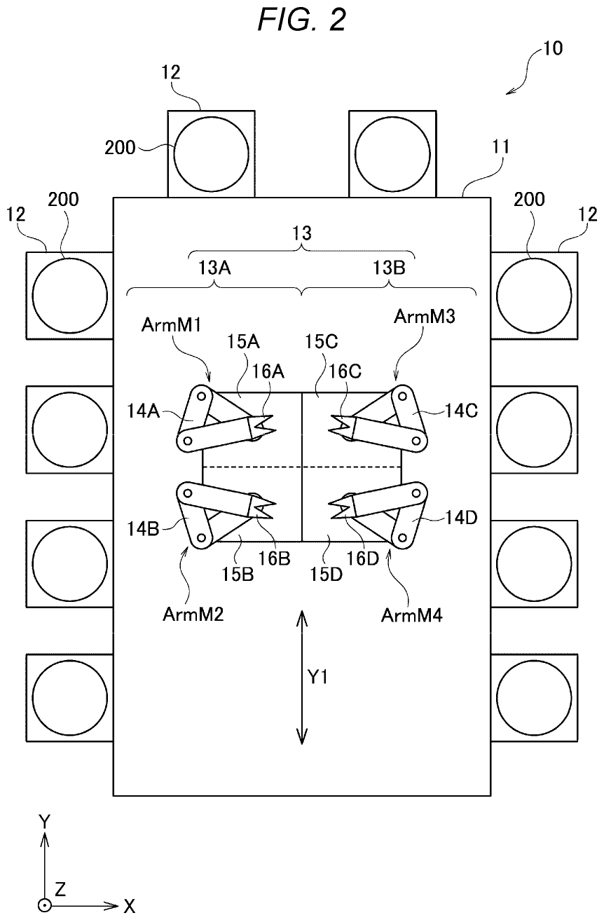

As illustrated in FIG. 1, the semiconductor manufacturing device 10 is in contact with the delivery unit 20. In the semiconductor manufacturing device 10, for example, fine uneven portions are formed on the front surfaces of substrates 200 of processing units 12. In the above description, the substrate 200 is also referred to as a wafer 200. In addition, a configuration of the semiconductor manufacturing device 10 is described, for example, in the description of FIG. 2.

As illustrated in FIG. 1, the delivery unit 20 is provided between the semiconductor manufacturing device 10 and the second conveyance unit 30. The delivery unit 20 includes a housing 21 and a mounting table 22. The delivery unit 20 can temporarily hold the wafers 200 for delivery, between the semiconductor manufacturing device 10 and the second conveyance unit 30.

The housing 21 has, for example, a box shape, and the mounting table 22 is provided in the housing 21. The housing 21 has an airtight structure to an extent in which particles and the like cannot enter from the outside. The atmosphere in the housing 21 is, for example, atmospheric pressure.

The wafer 200 is mounted on the mounting table 22. The delivery unit 20 is not necessarily required and may not be provided. The wafers 200 may be directly delivered, for example, between the first conveyance unit 11 and the second conveyance unit 30. Alternately, by providing the delivery unit 20, an operation in the first conveyance unit 11 and an operation in the second conveyance unit 30 can be performed in parallel. Therefore, waiting time that occurs when the wafers 200 are directly delivered between the first conveyance unit 11 and the second conveyance unit 30 can be reduced.

As illustrated in FIG. 1, the second conveyance unit 30 is provided between the delivery unit 20 and the integration unit 40. The second conveyance unit 30 includes a housing 31 and a transfer unit 32. The second conveyance unit 30 can convey the wafers 200.

The housing 31 has, for example, a box shape, and the transfer unit 32 is provided in the housing 31. The housing 31 has an airtight structure to an extent in which particles and the like cannot enter from the outside. The atmosphere inside the housing 31 is, for example, atmospheric pressure. In addition, the first conveyance unit 11, the processing units 12, the housing 21, and the housing 31 can be integrally formed or can be separately formed.

The transfer unit 32 conveys and delivers the wafers 200 between the delivery unit 20 and the integration unit 40. The transfer unit 32 can be a conveyance robot having an arm 33 that rotates about a rotation axis. A holding unit 35 that holds the wafer 200 is provided at the tip of the arm 33. A movement unit 34 is provided below the arm 33. The movement unit 34 can move in a conveyance direction X (a direction of an arrow X in FIG. 1). In addition, a position adjusting unit (not illustrated) that changes a position of the wafer 200 in a rotation direction or a position thereof in an elevating direction, a direction changing unit (not illustrated) that changes a direction of the arm 33, or the like may be provided. In addition, the transfer unit 32 is not limited to the illustrated one. The transfer unit 32 may have a structure capable of conveying and delivering the wafers 200 between the delivery unit 20 and the integration unit 40.

As illustrated in FIG. 1, the integration unit 40 is in contact with the second conveyance unit 30. The integration unit 40 includes a storage unit 41, a stand 42, and an opening and closing door 43.

The storage unit 41 stores the wafers 200. The number of the storage units 41 is not limited, but if the plurality of storage units 41 are provided, productivity can be improved. The storage unit 41 is, for example, a carrier that can store the wafers 200 in a stacked shape (multi-stage shape). Specifically, the storage unit 41 may be a front-opening unified pod (FOUP) for conveying and storing wafers used in a mini-environment type semiconductor factory. However, the storage unit 41 is not limited to FOUP or the like, and may be any one that can store the wafers 200.

The stand 42 is provided, for example, on a floor surface or a side surface of the housing 31 (a surface expanding in an X direction of FIG. 1). The storage unit 41 is mounted on an upper surface of the stand 42. The stand 42 can hold the mounted storage unit 41.

The opening and closing door 43 is provided between an opening of the storage unit 41 and an opening of the housing 31. The opening and closing door 43 opens and closes the opening of the storage unit 41. For example, the opening and closing door 43 is raised by a driving unit (not illustrated) in a Z direction, and thus the opening of the storage unit 41 can be closed. In addition, the opening and closing door 43 is lowered by the driving unit (not illustrated) in a −Z direction, and thus the opening of the storage unit 41 can be opened.

The controller 50 is spaced from the semiconductor manufacturing device 10, the delivery unit 20, the second conveyance unit 30, and the integration unit 40, and can remotely control an operation of each element. Specifically, the controller 50 can control the operation of each element, for example, by using a communication network. In addition, here, the communication network is not limited.

As illustrated in FIG. 1, the controller 50 includes a CPU 51 and a storage medium 52. The CPU 51 stores a program of a computer used in the wafer conveyance system 1. In addition, the storage medium 52 functions as a program storage device or the like that stores a program executed by the controller 50. In addition, the controller 50 executes a program of a computer used in the wafer conveyance system 1.

### Configuration of Semiconductor Manufacturing Device

FIG. 2 is a schematic diagram illustrating the configuration of the semiconductor manufacturing device 10.

As illustrated in FIG. 2, the semiconductor manufacturing device 10 includes the first conveyance unit 11, the processing units 12, first to fourth conveyance modules (ArmM1 to ArmM4), and a conveyance arm 13.

The first conveyance unit 11 is, for example, an equipment front end module (EFEM) and is a locally cleaned housing that allows a clean downflow airflow to flow in. In addition, the first conveyance unit 11 may be filled with nitrogen (N₂ purge).

As illustrated in FIG. 2, the first conveyance unit 11 has a rectangular shape, for example, having a short side in an X axis direction and a long side in a Y axis direction. Further, a plurality of processing units 12 are provided so that a side surface of the long side and an upper surface of the short side of the first conveyance unit 11 are in contact with each other. In addition, as illustrated in FIG. 2, the first conveyance unit 11 has a rectangular shape having the short side in the X axis direction and the long side in the Y axis direction, but the shape of the first conveyance unit 11 is not limited.

The processing unit 12 is, for example, a processing module, and is a process device portion for performing each step such as wafer cleaning, film formation, heat diffusion, and etching on the wafer 200.

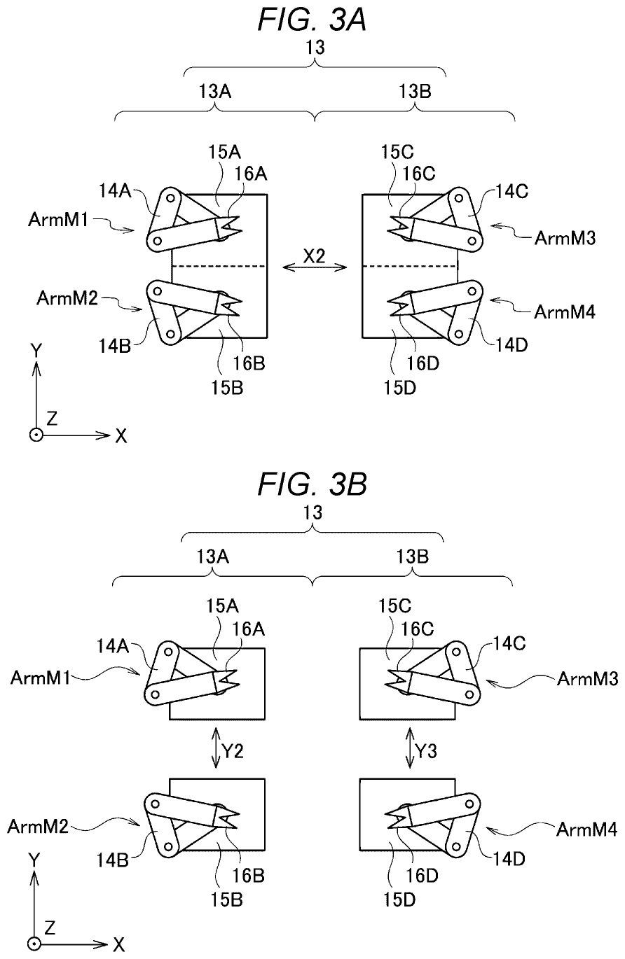

As illustrated in FIG. 2, the first to fourth conveyance modules (ArmM1 to ArmM4) are provided in the first conveyance unit 11. In addition, a plurality of modules (here, four modules) including the first to fourth conveyance modules (ArmM1 to ArmM4) may be provided. The number of the first to fourth conveyance modules (ArmM1 to ArmM4) is not particularly limited, and may be four or less or may be four or more. The first to fourth conveyance modules (ArmM1 to ArmM4) convey the wafers 200. In addition, configurations of the first to fourth conveyance modules (ArmM1 to ArmM4) are specifically described, for example, in the description of FIGS. 3A and 3B.

As illustrated in FIG. 2, the conveyance arm 13 includes a first conveyance arm 13A and a second conveyance arm 13B. The conveyance arm 13 can move in conveyance directions Y1 (two directions indicated by Y1 in FIG. 1). For example, in a normal operation mode, the conveyance arm 13 conveys the wafers 200 in a state where the first conveyance arm 13A and the second conveyance arm 13B are combined. In addition, a configuration of the conveyance arm 13 is specifically described in the descriptions of FIGS. 3A and 3B.

### Configuration of Conveyance Arm

FIG. 3A is a schematic diagram illustrating the configuration of the conveyance arm 13.

As indicated by a bidirectional arrow X2 in FIG. 3A, in the conveyance arm 13, the first conveyance arm 13A and the second conveyance arm 13B can be combined with and/or separated from each other.

The first conveyance arm 13A is formed, for example, by combining the first conveyance module (ArmM1) and the second conveyance module (ArmM2). The second conveyance arm 13B is formed, for example, by combining the third conveyance module (ArmM3) and the fourth conveyance module (ArmM4).

As illustrated in FIG. 2, for example, the first conveyance arm 13A can convey the wafers 200 to the processing units 12 that are in contact with a left side surface and the upper surface of the first conveyance unit 11. For example, the second conveyance arm 13B can convey the wafers 200 to the processing units 12 that are in contact with a right side surface and the upper surface of the first conveyance unit 11.

### Configuration of Conveyance Module

FIG. 3B is a schematic diagram illustrating configurations of the first to fourth conveyance modules (ArmM1 to ArmM4).

As illustrated in FIG. 3B, the first to fourth conveyance modules (ArmM1 to ArmM4) include arm driving units (14A to 14D) and arm supporting units (15A to 15D). In addition, the first to fourth conveyance modules (ArmM1 to ArmM4) may include, for example, arm holding units (16A to 16D) that hold the wafers 200.

The first to fourth conveyance modules (ArmM1 to ArmM4) can independently drive the arm driving units (14A to 14D), the arm supporting units (15A to 15D), and the arm holding units (16A to 16D). In addition, as illustrated in a bidirectional arrow Y2 in FIG. 3B, for example, the first to fourth conveyance modules (ArmM1 to ArmM4) can combine and/or separate the first conveyance module (ArmM1) and the second conveyance module (ArmM2). In addition, as illustrated in a bidirectional arrow Y3 in FIG. 3B, the third conveyance module (ArmM3) and the fourth conveyance module (ArmM4) are combined with and/or separated from each other. That is, among the first to fourth conveyance modules (ArmM1 to ArmM4), even when a failure occurs in the first conveyance module (ArmM1), the second to fourth conveyance modules (ArmM2 to ArmM4) can continue the wafer conveyance independently from the failed first conveyance module (ArmM1). In the following description, the failure is referred to as an error.

### Wafer Conveyance Method

Subsequently, an outline of a wafer conveyance method of the wafer conveyance system 1 according to the first embodiment is described.

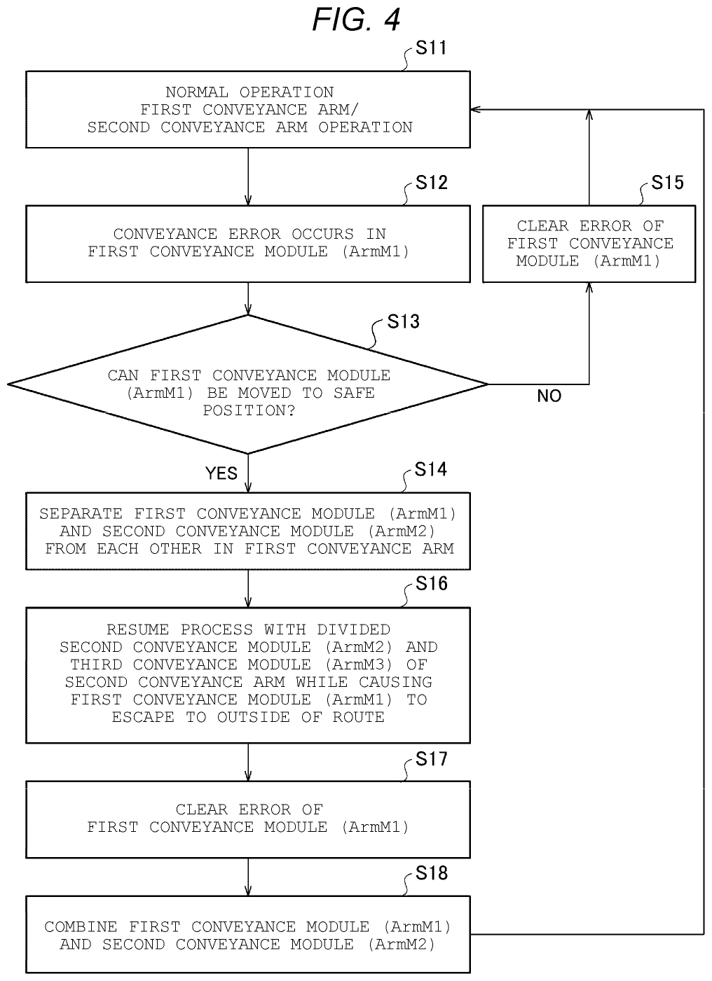

FIG. 4 is a flowchart illustrating an example of a flow of operations of the wafer conveyance method when the error occurs.

First, the CPU 51 conveys the wafers 200 by using the first conveyance arm 13A and the second conveyance arm 13B as the normal operation mode.

Subsequently, the CPU 51 checks whether there is an abnormality in the first to fourth conveyance modules (ArmM1 to ArmM4) in the normal operation mode. In addition, when an error occurs in the first to fourth conveyance modules (ArmM1 to ArmM4), the CPU 51 stops the normal operation mode and starts a recovery operation mode. In the following description, the conveyance module in which an error occurs is described as the first conveyance module (ArmM1).

In the recovery operation mode, the CPU 51 checks whether the first conveyance module (ArmM1) can move. When the first conveyance module (ArmM1) can move, the CPU 51 separates the first conveyance module (ArmM1) so that the first conveyance module (ArmM1) escapes to a location where the error can be cleared. When the first conveyance module (ArmM1) escapes, the CPU 51 resumes the wafer conveyance by using the first conveyance arm 13A and the second conveyance arm 13B that perform normal operations. When the first conveyance module (ArmM1) cannot move, the CPU 51 stops the wafer conveyance, clears the error of the first conveyance module (ArmM1), and returns to the normal operation mode.

The CPU 51 clears the error of the first conveyance module (ArmM1) while the wafer conveyance is resumed.

When verifying that the error of the first conveyance module (ArmM1) is cleared, the CPU 51 stops the wafer conveyance, moves the first conveyance module (ArmM1) to a position of the first conveyance arm 13A, and returns from the recovery operation mode to the normal operation mode.

Subsequently, the wafer conveyance method of the wafer conveyance system 1 according to the first embodiment is described in detail.

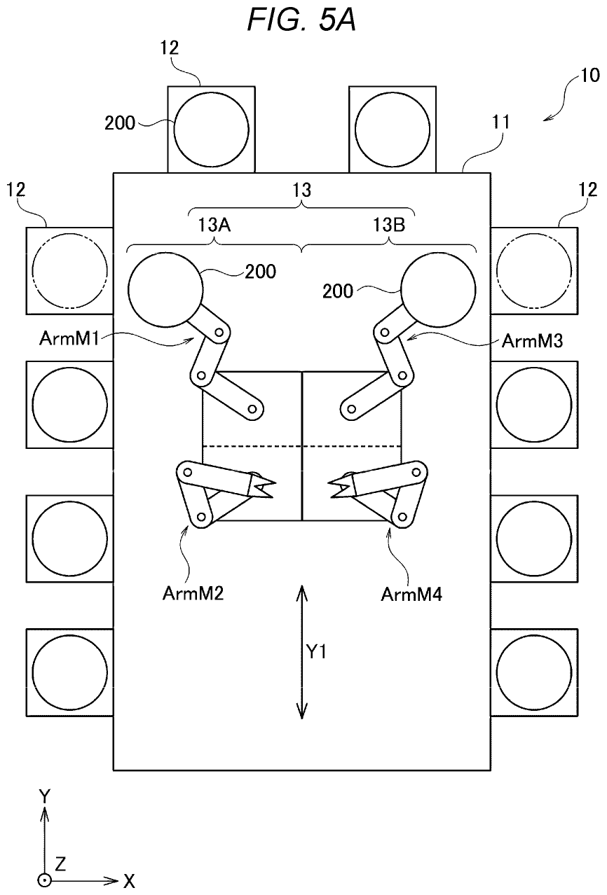

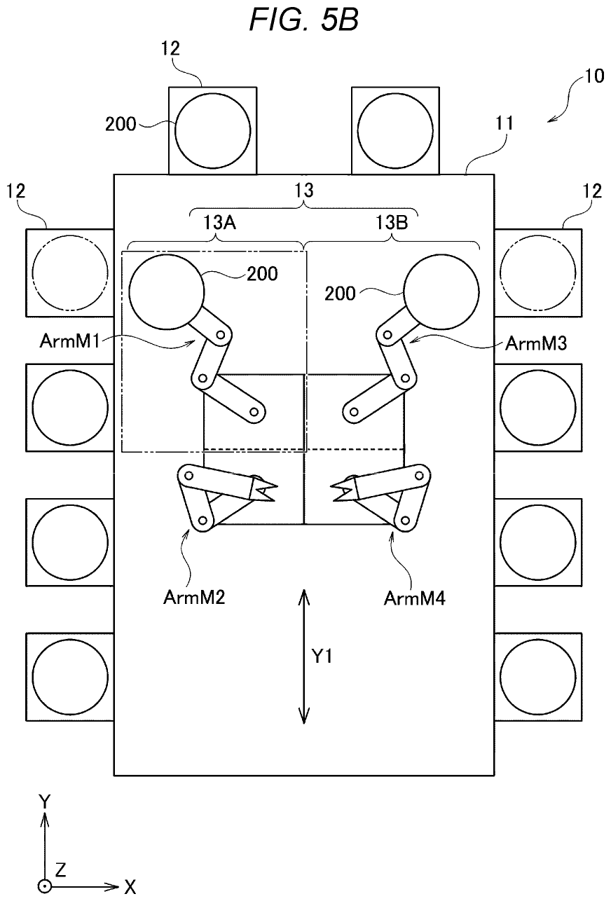

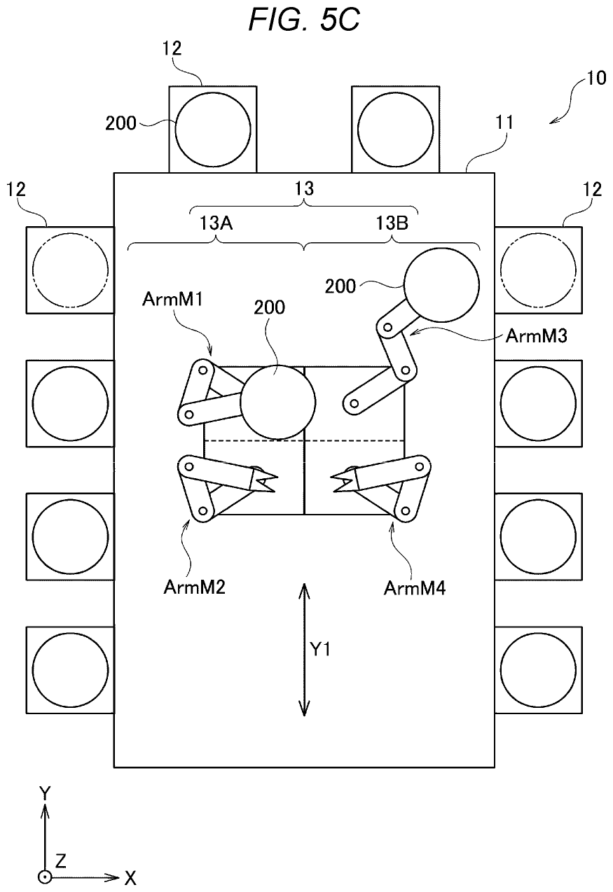

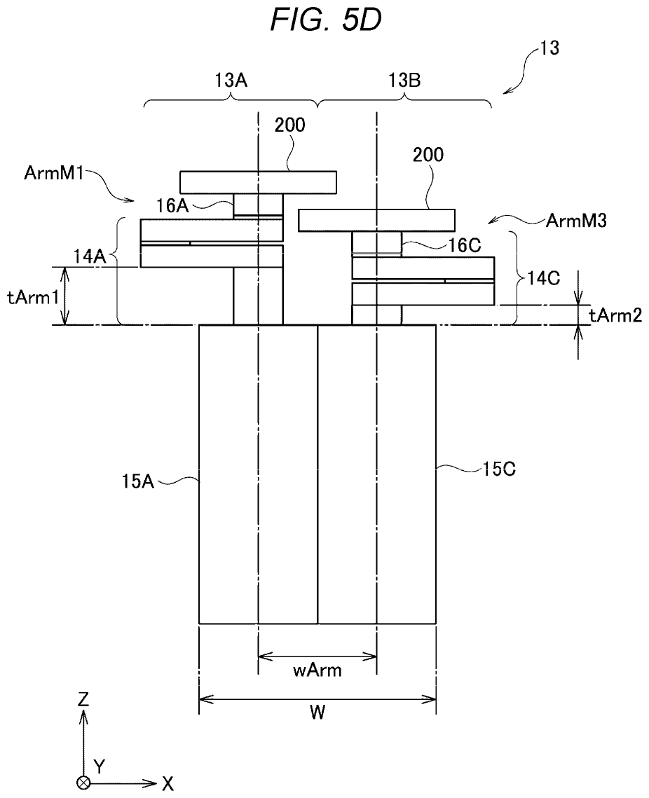

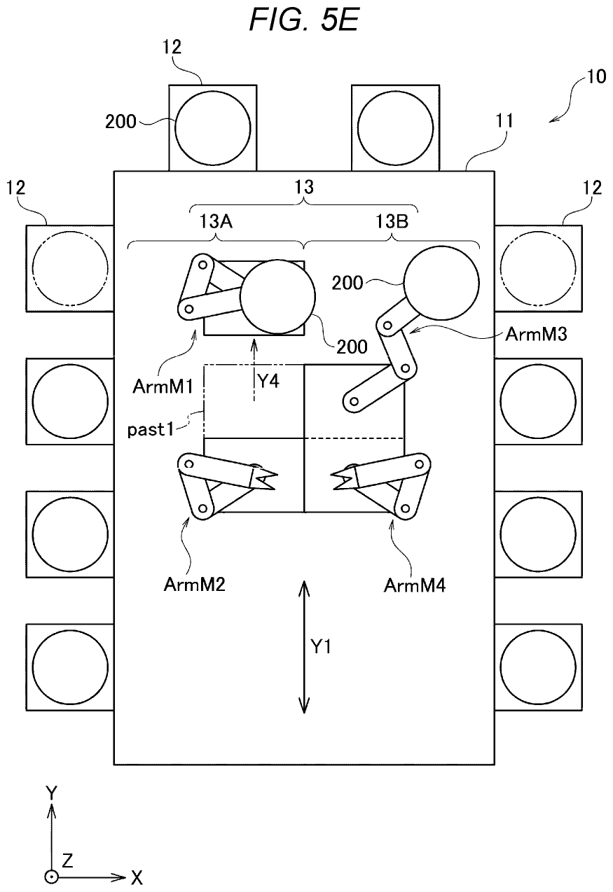

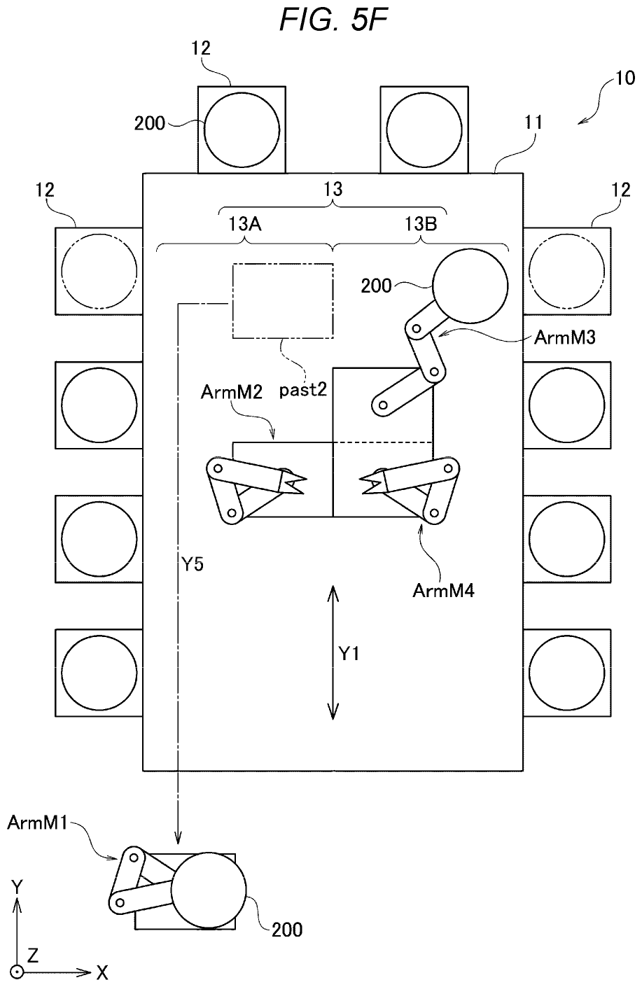

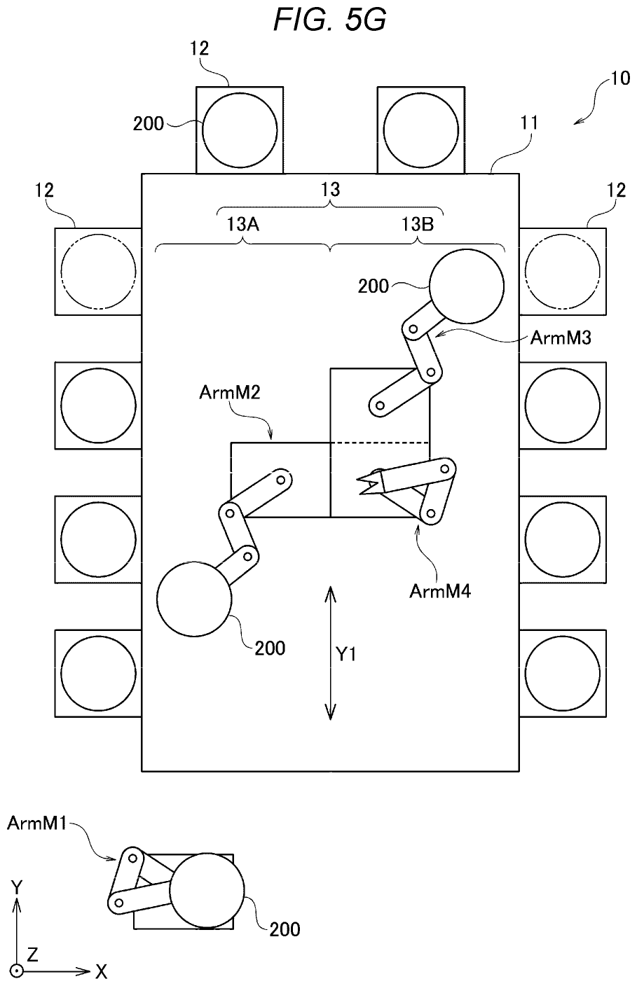

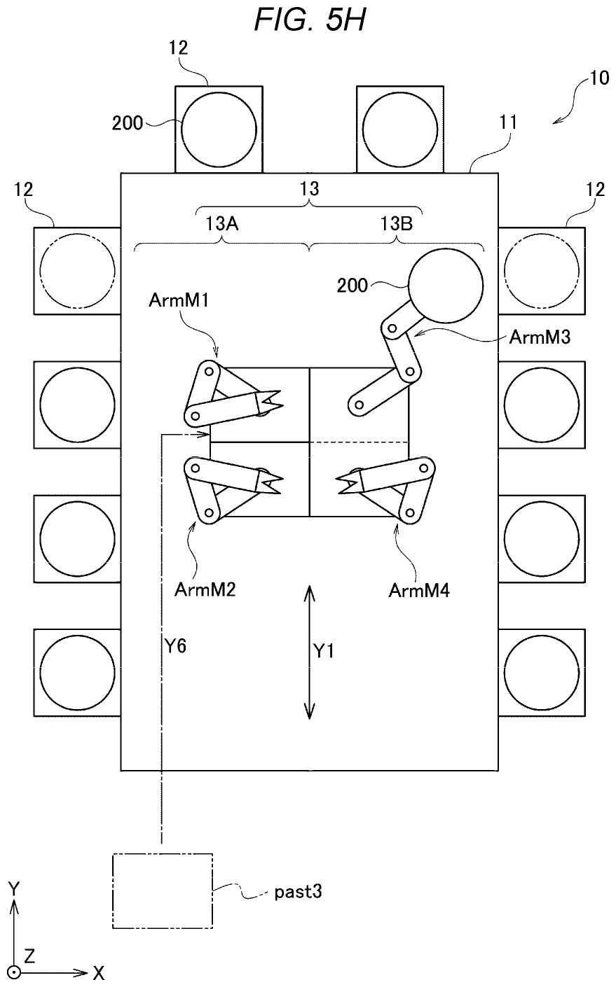

FIG. 5A is a plan view illustrating the semiconductor manufacturing device 10 in the normal operation mode. FIG. 5B is a plan view illustrating the semiconductor manufacturing device 10 when a conveyance error occurs. FIG. 5C is a plan view illustrating the semiconductor manufacturing device 10 after the conveyance error occurs. FIG. 5D is a side view illustrating the semiconductor manufacturing device 10 after the conveyance error occurs. FIG. 5E is a plan view illustrating the semiconductor manufacturing device 10 when the first conveyance module (ArmM1) and the second conveyance module (ArmM2) are separated from each other. FIG. 5F is a plan view illustrating the semiconductor manufacturing device 10 when the first conveyance module (ArmM1) is retracted. FIG. 5G is a plan view illustrating the semiconductor manufacturing device 10 when a process is resumed. FIG. 5H is a plan view illustrating the semiconductor manufacturing device 10 when the first conveyance module (ArmM1) in which the conveyance error is cleared and the second to fourth conveyance modules (ArmM2 to ArmM4) are combined.

First, in Step S11, as illustrated in FIG. 5A, the CPU 51 conveys the wafers 200 by using the first conveyance arm 13A and the second conveyance arm 13B as the normal operation mode. Specifically, the first conveyance arm 13A conveys the wafers 200 by any one conveyance module (here, the first conveyance module (ArmM1)) among the first conveyance module (ArmM1) and the second conveyance module (ArmM2). Similarly, the second conveyance arm 13B conveys the wafers 200 by any one conveyance module (here, the third conveyance module (ArmM3)) among the third conveyance module (ArmM3) and the fourth conveyance module (ArmM4). In addition, the CPU 51 may check whether there is no error in the first to fourth conveyance modules (ArmM1 to ArmM4) in the normal operation mode. The CPU 51 can find an error at an early stage by appropriately checking errors.

Next, in Step S12, as illustrated in FIG. 5B, the CPU 51 detects whether an error occurs in the first conveyance module (ArmM1) during the conveyance, to stop the wafer conveyance. Specifically, the conveyance arm 13 stops the wafer conveyance. That is, the CPU 51 switches from the normal operation mode to the recovery operation mode.

In Step S13, the CPU 51 checks whether the first conveyance module (ArmM1) can move to a safe position as the recovery operation mode. Here, the safe position refers to an outside of a route through which the conveyance arm 13 conveys the wafers. Specifically, the CPU 51 determines, for example, based on information such as an error status of an arm supporting unit 15A and a conveyance status of the conveyance arm 13. In addition, the first conveyance module (ArmM1) may move an arm driving unit 14A to a predetermined stable position, for example, by an instruction of the CPU 51. Here, the predetermined stable position refers to a state, for example, in which the arm driving unit 14A is folded as illustrated in FIG. 5C. In addition, the predetermined stable position is not limited to a state in which the arm driving unit 14A is folded and may be a position where the wafer 200 held by an arm holding unit 16A is stable.

Next, as illustrated in FIG. 5D, the CPU 51 performs a change to a height tArm1 of the arm driving unit 14A of the first conveyance module (ArmM1). That is, the first conveyance module (ArmM1) moves to the height tArm1 that does not interfere with a height tArm2 of an operation range of the third conveyance module (ArmM3) in the normal operation mode. That is, by the change to the height tArm1 of the arm driving unit 14A, interference between the wafer 200 of the first conveyance arm 13A and the wafer 200 of the second conveyance arm 13B is avoided, a distance wArm between the first conveyance module (ArmM1) and the third conveyance module (ArmM3) can be narrowed down. Therefore, by narrowing down the distance wArm between the first conveyance module (ArmM1) and the third conveyance module (ArmM3), a width W between the first conveyance module (ArmM1) and the third conveyance module (ArmM3) can be saved.

Further, when the first conveyance module (ArmM1) can move to the safe position, the process proceeds to Step S14. When the first conveyance module (ArmM1) cannot move to the safe position, the process proceeds to Step S15.

In Step S14, as illustrated in FIG. 5E, the CPU 51 separates the first conveyance module (ArmM1) and the second conveyance module (ArmM2) from each other in the first conveyance arm 13A. Specifically, as indicated by a one-way arrow Y4 in FIG. 5E, the first conveyance module (ArmM1) is separated from the second to fourth conveyance modules (ArmM2 to ArmM4) from a previous position past1. That is, the first conveyance module (ArmM1) moves to the safe position.

In Step S15, the CPU 51 clears the error of the first conveyance module (ArmM1) (not illustrated). Specifically, since it is difficult for the first conveyance module (ArmM1) to move to the safe position according to the determination of the CPU 51, the error is cleared without moving the first conveyance module (ArmM1). That is, after the error is cleared, the first conveyance arm 13A and the second conveyance arm 13B return to Step S11 that is the normal operation mode.

In Step S16, as illustrated in FIG. 5F, the CPU 51 causes the first conveyance module (ArmM1) to escape to the outside of the route through which the conveyance arm 13 conveys the wafers. Specifically, as indicated by a one-way arrow Y5 in FIG. 5F, the first conveyance module (ArmM1) moves from a previous position past2 to an outside of the first conveyance unit 11 via an outside of an operation range of the second to fourth conveyance modules (ArmM2 to ArmM4). In addition, although not illustrated, the first conveyance module (ArmM1) may move into the first conveyance unit 11 via the outside of the operation range of the second to fourth conveyance modules (ArmM2 to ArmM4). That is, as long as the first conveyance module (ArmM1) can temporarily escape in order to clear the error, the location for escape is not particularly limited.

Next, as illustrated in FIG. 5G, the CPU 51 resumes the processes of wafer conveyance with the second conveyance module (ArmM2) of the first conveyance arm 13A and the third conveyance module (ArmM3) of the second conveyance arm 13B in the conveyance arm 13. Specifically, for example, the processes of wafer conveyance are resumed with the second conveyance module (ArmM2) in which an error does not occur in the first conveyance arm 13A, and the third conveyance module (ArmM3) of the second conveyance arm 13B. That is, the conveyance arm 13 resumes the processes of wafer conveyance with the second to fourth conveyance modules (ArmM2 to ArmM4) other than the first conveyance module (ArmM1). That is, since the processes can be performed even while the error of the first conveyance module (ArmM1) is cleared, an operation stop time can be shortened as compared with an operation stop time when the error of the first conveyance module (ArmM1) of Step S15 is cleared and recovered.

In Step S17, the CPU 51 clears the error of the first conveyance module (ArmM1) (not illustrated).

In Step S18, as illustrated in FIG. 5H, the CPU 51 combines the first conveyance module (ArmM1) and the second conveyance module (ArmM2). Specifically, for example, as indicated by a one-way arrow Y6 in FIG. 5H, the first conveyance module (ArmM1) is combined with the second to fourth conveyance modules (ArmM2 to ArmM4) from a previous position past3. That is, the first conveyance module (ArmM1) moves to an original position in the first conveyance arm 13A. Accordingly, the first conveyance arm 13A and the second conveyance arm 13B return to the normal operation mode.

By the above wafer conveyance method, the wafer conveyance of the wafer conveyance system 1 is completed.

In the wafer conveyance system 1 according to the first embodiment, since the first conveyance module (ArmM1) and the second conveyance module (ArmM2) that can be combined with and/or separated from each other are provided, even when an error occurs in the first conveyance module (ArmM1) and the second conveyance module (ArmM2), the conveyance arm 13 can continue the wafer conveyance.

In addition, in the wafer conveyance system 1 according to the first embodiment, since the wafer conveyance is continued even while the error of the first conveyance module (ArmM1) is cleared, the operation stop time can be shortened as compared with the operation stop time when the error of the first conveyance module (ArmM1) is cleared and recovered. It should be noted that the wafer conveyance method illustrated to FIG. 4 can also be described in a computer program as instructions to be executed by computers. The computer program is stored in, for example, a non-transitory computer readable medium and is used for wafer conveyance method.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor manufacturing device comprising:
a first conveyance unit;
a processing unit in contact with the first conveyance unit;
a conveyance module provided in the first conveyance unit and including an arm driving unit and an arm supporting unit; and
a conveyance arm including a first conveyance module and a second conveyance module that can be driven independently,
wherein the first conveyance module and the second conveyance module can be physically combined with and/or separated from each other.

2. The semiconductor manufacturing device according to claim 1,
wherein the conveyance arm includes a first conveyance arm and a second conveyance arm,
the first conveyance arm includes the first conveyance module and the second conveyance module that can be physically combined with and/or separated from each other, and
the second conveyance arm includes a third conveyance module and a fourth conveyance module that can be physically combined with and/or separated from each other.

3. The semiconductor manufacturing device according to claim 2,
wherein at least one of the first conveyance module or the second conveyance module in the first conveyance arm is configured to convey a wafer, and
at least one of the third conveyance module or the fourth conveyance module in the second conveyance arm is configured to convey a wafer.

4. The semiconductor manufacturing device according to claim 2,
wherein, in the first conveyance arm, the first conveyance module and the second conveyance module can be physically separated from each other when a failure occurs in the first conveyance module, and
in the second conveyance arm, the third conveyance module and the fourth conveyance module can be physically separated from each other when a failure occurs in the third conveyance module.

5. The semiconductor manufacturing device according to claim 2,
wherein the first conveyance arm is configured to continue conveyance with the second conveyance module when a failure occurs in the first conveyance module, and
the second conveyance arm is configured to continue conveyance with the fourth conveyance module when a failure occurs in the third conveyance module.

6. The semiconductor manufacturing device according to claim 2,
wherein the first conveyance arm is configured to change a height of the arm driving unit of the first conveyance module and a height of at least one of an arm driving unit in the third conveyance module or an arm driving unit in the fourth conveyance module, when a failure occurs in the first conveyance module, and
the second conveyance arm is configured to change a height of the arm driving unit of the third conveyance module and a height of at least one of the arm driving unit in the first conveyance module or an arm driving unit of the second conveyance module, when a failure occurs in the third conveyance module.

7. A wafer conveyance system comprising:
the semiconductor manufacturing device according to claim 1;
a delivery unit, in contact with the semiconductor manufacturing device, that is configured to temporarily hold a substrate in the semiconductor manufacturing device;
a second conveyance unit, in contact with the delivery unit, that is configured to convey the substrate to the delivery unit;
an integration unit, in contact with the second conveyance unit, that is configured to store the substrate; and
a controller, spaced from the semiconductor manufacturing device, the delivery unit, the second conveyance unit, and the integration unit, that is configured to remotely control an operation of each element.

8. A wafer conveyance method comprising:
conveying a substrate based on a first conveyance arm and a second conveyance arm;
checking whether there is no abnormality in any of first, second, third, and fourth conveyance modules;
stopping a normal operation mode and starting a recovery operation mode when an error occurs in the first conveyance module;
checking whether the first conveyance module can move in the recovery operation mode;
separating the first conveyance module and the second conveyance module from each other, thereby causing the first conveyance module to escape to a location where an error can be cleared when the first conveyance module can move;
resuming wafer conveyance based on the first conveyance arm and the second conveyance arm that perform a normal operation;
clearing the error of the first conveyance module while wafer conveyance is resumed; and
moving the first conveyance module to a position of the first conveyance arm after the error of the first conveyance module is cleared.

9. The wafer conveyance method according to claim 8,
wherein at least one of the first conveyance module or the second conveyance module in the first conveyance arm conveys a wafer, and
at least one of the third conveyance module or the fourth conveyance module in the second conveyance arm conveys a wafer.

10. The wafer conveyance method according to claim 8,
wherein, in the first conveyance arm, the first conveyance module and the second conveyance module are physically separated from each other when a failure occurs in the first conveyance module, and
in the second conveyance arm, the third conveyance module and the fourth conveyance module are physically separated from each other when a failure occurs in the third conveyance module.

11. The wafer conveyance method according to claim 8,
wherein the first conveyance arm is configured to continue conveyance with the second conveyance module when a failure occurs in the first conveyance module, and
the second conveyance arm is configured to continue conveyance with the fourth conveyance module when a failure occurs in the third conveyance module.

12. The wafer conveyance method according to claim 8,
wherein the first conveyance arm is configured to change a height of an arm driving unit of the first conveyance module and a height of at least one of an arm driving unit in the third conveyance module or an arm driving unit in the fourth conveyance module, when a failure occurs in the first conveyance module, and
the second conveyance arm is configured to change a height of the arm driving unit of the third conveyance module and a height of at least one of the arm driving unit in the first conveyance module or an arm driving unit in the second conveyance module, when a failure occurs in the third conveyance module.

13. A non-transitory computer readable medium in which a computer program is stored, the computer program being executed by a computer used for a wafer conveyance system, the program causing the computer to execute:
conveying a substrate based on a first conveyance arm and a second conveyance arm;
checking whether there is no abnormality in any of first, second, third, and fourth conveyance modules;
stopping a normal operation mode and starting a recovery operation mode when an error occurs in the first conveyance module;
checking whether the first conveyance module can move in the recovery operation mode;
separating the first conveyance module and the second conveyance module from each other thereby causing the first conveyance module to escape to a location where an error can be cleared when the first conveyance module can move;
resuming wafer conveyance based on the first conveyance arm and the second conveyance arm that perform a normal operation;
clearing the error of the first conveyance module while wafer conveyance is resumed; and
moving the first conveyance module to a position of the first conveyance arm after the error of the first conveyance module is cleared.
